(19) United States
(12) Patent Application Publication
(10) Pub. No.: US 2025/0227431 A1
(43) Pub. Date: Jul. 10, 2025

(54) REVERBERATION PROCESSING METHOD AND APPARATUS, AND NON-TRANSITORY COMPUTER READABLE STORAGE MEDIUM

(71) Applicant: Douyin Vision Co., Ltd., Beijing (CN)

(72) Inventors: Xuzhou YE, Beijing (CN); Junjie Shi, Beijing (CN); Zhengpu Zhang, Beijing (CN); Derong Liu, Beijing (CN); Shilei Liu, Beijing (CN); Chuanzeng Huang, Beijing (CN)

(21) Appl. No.: 19/094,699

(22) Filed: Mar. 28, 2025

Related U.S. Application Data
(63) Continuation of application No. PCT/CN2023/121368, filed on Sep. 26, 2023.

(30) Foreign Application Priority Data
Sep. 30, 2022 (WO) PCT/CN2022/123290

(51) Int. Cl. H04S 7/00; H04S 3/00

(52) U.S. Cl. CPC H04S 7/305; H04S 3/008; H04S 7/302; H04S 7/307; H04S 2400/01; H04S 2400/11; H04S 2400/13

(57) ABSTRACT

A reverberation processing method and apparatus, and a non-transitory computer readable storage medium. The reverberation processing method includes: estimating shape information of a scene according to a plurality of intersection points of a plurality of sound rays centered on a listener with the scene; calculating a first average acoustic parameter value of a scene material of the scene according to first acoustic parameter values of scene materials at positions of the plurality of intersection points; and calculating a reverberation time according to the shape information of the scene and the first average acoustic parameter value.

### CROSS-REFERENCE TO RELATED APPLICATIONS

This application is a Continuation of the PCT Application No. PCT/CN2023/121368 filed on Sep. 26, 2023, which is based on International Application number PCT/CN2022/123290 and filing date of Sep. 30, 2022, and claims its priority. The disclosures of these PCT applications as a whole are incorporated into the present application herein by reference in their entireties.

### TECHNICAL FIELD

This disclosure relates to the technical field of audio processing, in particular to a reverberation processing method, a reverberation processing device and a non-transitory computer-readable storage medium.

### BACKGROUND

Environmental acoustic phenomena are ubiquitous in reality. Therefore, in an immersive virtual environment, in order to simulate the various information that the real world gives to humans as much as possible, it is necessary to simulate the impact of virtual scenes on sound in the scene with high quality, so as not to break the user's sense of immersion.

In related arts, there are mainly three categories of methods to simulate environmental acoustic phenomena: wave solvers based on finite element analysis, ray tracing and simplification of the geometric shape of the environment.

### SUMMARY

According to some embodiments of the present disclosure, there is provided a reverberation processing method, including:
estimating shape information of a scene according to a plurality of intersection points of a plurality of sound rays centered on a listener with the scene;
calculating a first average acoustic parameter value of a scene material of the scene according to first acoustic parameter values of scene materials at positions of the plurality of intersection points; and
calculating a reverberation time according to the shape information of the scene and the first average acoustic parameter value.

In some embodiments, the estimating the shape information of the scene according to the plurality of intersection points of the plurality of sound rays centered on the listener with the scene includes:
calculating an average coordinate of an intersection point according to an average value of coordinates of the plurality of intersection points; and estimating the shape information of the scene according to an average value of distances between each of the plurality of intersection points and the average intersection point.

In some embodiments, the calculating the first average acoustic parameter value of the scene material of the scene according to the first acoustic parameter values of the scene materials at the positions of the plurality of intersection points includes:
calculating an average absorption rate of the scene material of the scene according to an average value of absorption rates of the scene materials at the positions of the plurality of intersection points.

In some embodiments, a shape of the scene is a cube, and the shape information includes a side length of the cube.

In some embodiments, the calculating the reverberation time according to the shape information of the scene and the first average acoustic parameter value includes:
calculating the reverberation time according to a side length of the scene and the average absorption rate of the scene material of the scene.

In some embodiments, the processing method further includes:
calculating a second average acoustic parameter value of the scene material of the scene according to second acoustic parameter values of the scene materials at the positions of the plurality of intersection points; and
performing a reverberation processing on a sound source signal according to the second average acoustic parameter value and the reverberation time.

In some embodiments, the calculating the second average acoustic parameter value of the scene material of the scene according to the second acoustic parameter values of the scene materials at the positions of the plurality of intersection points includes:
calculating an average scattering rate of the scene material of the scene according to an average value of scattering rates of the scene materials at the positions of the plurality of intersection points.

In some embodiments, the performing the reverberation processing on the sound source signal includes:
performing a filtering processing on the sound source signal using an all-pass filter, where the all-pass filter is controlled according to the second average acoustic parameter value.

In some embodiments, the performing the reverberation processing on the sound source signal includes:
performing the reverberation processing using one or more feedback gains based on a result of the filtering processing, where the one or more feedback gains are controlled according to the reverberation time.

In some embodiments, the one or more feedback gains are a plurality of feedback gains, and each of the plurality of feedback gains is determined according to a corresponding delay time.

In some embodiments, the performing the reverberation processing using the one or more feedback gains based on the result of the filtering processing includes:
performing a delay processing on the result of the filtering processing; processing a result of the delay processing using a reflection matrix; and processing a processing result of the reflection matrix using the one or more feedback gains.

In some embodiments, the performing the delay processing on the result of the filtering processing includes:
performing the delay processing on the result of the filtering processing respectively using a plurality of delay times.

In some embodiments, the performing the delay processing on the result of the filtering processing includes:
performing the delay processing on a sum of the result of the filtering processing and a processing result using the one or more feedback gains.

According to other embodiments of the present disclosure, there is provided a reverberation processing device, including:
an estimation unit configured to estimate shape information of a scene according to a plurality of intersection points of a plurality of sound rays centered on a listener with the scene; and
a calculation unit configured to calculate a first average acoustic parameter value of a scene material of the scene according to first acoustic parameter values of scene materials at positions of the plurality of intersection points, and calculate a reverberation time according to the shape information of the scene and the first average acoustic parameter value.

In some embodiments, the estimation unit calculates a coordinate of an average intersection point according to an average value of coordinates of the plurality of intersection points; and estimates the shape information of the scene according to an average value of distances between each of the plurality of intersection points and the average intersection point.

In some embodiments, the calculation unit calculates an average absorption rate of the scene material of the scene according to an average value of absorption rates of the scene materials at the positions of the plurality of intersection points.

In some embodiments, a shape of the scene is a cube, and the shape information includes a side length of the cube.

In some embodiments, the calculation unit calculates the reverberation time according to a side length of the scene and the average absorption rate of the scene material of the scene.

In some embodiments, the calculation unit calculates a second average acoustic parameter value of the scene material of the scene according to second acoustic parameter values of the scene materials at the positions of the plurality of intersection points; and the processing device further includes a processing unit configured to perform a reverberation processing on a sound source signal according to the second average acoustic parameter value and the reverberation time.

In some embodiments, the calculation unit calculates an average scattering rate of the scene material of the scene according to an average value of scattering rates of the scene materials at the positions of the plurality of intersection points.

In some embodiments, the processing unit performs a filtering processing on the sound source signal using an all-pass filter, where the all-pass filter is controlled according to the second average acoustic parameter value.

In some embodiments, the processing unit performs the reverberation processing using one or more feedback gains based on a result of the filtering processing, where the one or more feedback gains are controlled according to the reverberation time.

In some embodiments, the one or more feedback gains are a plurality of feedback gains, and each of the plurality of feedback gains is determined according to a corresponding delay time.

In some embodiments, the processing unit performs a delay processing on the result of the filtering processing; processes a result of the delay processing using a reflection matrix; and processes a processing result of the reflection matrix using the one or more feedback gains.

In some embodiments, the processing unit performs the delay processing on the result of the filtering processing respectively using a plurality of delay times.

In some embodiments, the processing unit performs the delay processing on a sum of the result of the filtering processing and a processing result using the one or more feedback gains.

According to still other embodiments of the present disclosure, there is provided a reverberation processing device, including:
a memory; and
a processor coupled to the memory, the processor configured to carry out a reverberation processing method according to any one of the above embodiments based on instructions stored in the memory.

According to still further embodiments of the present disclosure, there is provided a computer-readable storage medium stored thereon a computer program that, when executed by a processor, carries out a reverberation processing method according to any one of the above embodiments.

According to still further embodiments of the present disclosure, there is also provided a computer program including instructions that, when executed by a processor, cause the processor to carry out a reverberation processing method according to any one of the above embodiments.

According to still further embodiments of the present disclosure, there is also provided a computer program product including instructions that, when executed by a processor, cause the processor to carry out a reverberation processing method according to any one of the above embodiments.

Other features and advantages of the present disclosure will become clear through detailed descriptions of the exemplary embodiments of the present disclosure with reference to the following accompanying drawings.

### BRIEF DESCRIPTION OF THE DRAWINGS

The drawings described herein are used to provide further understanding of the present disclosure, which constitute a portion of the present application. The schematic embodiments and description of the present disclosure are only used for explaining the present disclosure, and do not constitute improper delimitations of the present disclosure. In the accompanying drawings:

FIG. 1 shows a flow diagram of a reverberation processing method according to some embodiments of the present disclosure;

FIG. 2 shows a schematic diagram of a spatial audio rendering system framework according to some embodiments of the present disclosure;

FIGS. 3a-3c show schematic diagrams of a reverberation processing method according to some embodiments of the present disclosure;

FIG. 4 shows a block diagram of a reverberation processing device according to some embodiments of the present disclosure;

FIG. 5 shows a block diagram of a reverberation processing device according to other embodiments of the present disclosure;

FIG. 6 shows a block diagram of a reverberation processing device according to further embodiments of the present disclosure.

### DETAILED DESCRIPTION

The technical solutions in the embodiments of the present disclosure will be clearly and completely described below with reference to the accompanying drawings in the embodiments of the present disclosure. Obviously, the described embodiments are only a part of the embodiments of the present disclosure instead of all of them. The following descriptions on at least one illustrative embodiment are actually illustrative, but shall not be construed as any limitation on the present disclosure and its application or utilization. All other embodiments that are obtainable to those skilled in the art based on the embodiments of the present disclosure without any creative effort are included in the protection scope of the present disclosure.

Unless otherwise specifically stated, the relative arrangements, mathematic expressions and values of the components and steps illustrated in these embodiments do not limit the scope of the present disclosure. Meanwhile, it shall be understood that for ease of description, the dimensions of various parts shown in the drawings are not drawn according to actual proportional relations. Techniques, methods and devices that have already been known to ordinary skilled in the art may not be discussed here in details, but under suitable circumstances, the techniques, methods and devices shall be deemed as parts of the authorized description. In all examples shown and discussed here, any specific values should be interpreted as merely illustrative and not as limitations. Therefore, other examples of exemplary embodiments may have different values. It should be noted that similar numerals and letters indicate similar items in the following drawings, so once an item is defined in one drawing, it does not need to be further discussed in subsequent drawings.

All sounds in the real world are spatial audio. Sound originates from the vibration of objects and is heard after propagating through a medium. In the real world, vibrating objects can appear anywhere, and they may form a three-dimensional direction vector with the human head. The horizontal angle of the direction vector may affect the loudness difference, time difference and phase difference of the sound reaching both ears, and the vertical angle of the direction vector may also affect the frequency response of the sound reaching both ears. It is by relying on these physical information that human beings acquire the ability to determine the position of a sound source according to binaural sound signals under a lot of acquired and unconscious training.

In an immersive virtual environment, in order to simulate various information that the real world gives to human as much as possible, it is also necessary to simulate the impact of sound position on the binaural signals heard in high quality, so as not to break the user's sense of immersion. This impact determines the position of the sound source and the position of the listener in a static environment. In this case, it can be expressed by HRTF (Head Related Transfer Function). HRTF is a two-channel FIR (Finite Impulse Response) filter. By convolving the original signal with the HRTF at a designated position, the signal heard in a case where the sound source is at the designated position can be obtained.

However, one HRTF can only represent the relative position relationship between one fixed sound source and one definite listener. In a case where N sound sources need to be rendered, N HRTFs are needed theoretically to perform 2N convolutions on the N original signals. Moreover, in a case where the listener rotates, all N HRTFs need to be updated to correctly render the virtual spatial audio scene, resulting in a large amount of computation.

In order to solve the problem of multi-source rendering and 3DOF (3 Degrees of Freedom) rotation of the listener, spherical harmonics are applied to spatial audio rendering. The basic idea of spherical harmonics (Ambisonic) is to imagine that the sound is distributed on a sphere, and N signal channels pointing in different directions perform their respective duties and are responsible for the sound in the corresponding direction. The spatial audio rendering algorithm based on ambisonics is as follows:
In step 1, all sampling points in each ambisonics channel are set to 0;
In step 2, the weight value of each ambisonics channel is calculated using the horizontal angle and pitch angle of the sound source relative to the listener;
In step 3, the original signal is multiplied by the weight value of each ambisonics channel, and the weighted signal is superimposed on each channel;
In step 4, step 3 is repeated for all sound sources in the scene;
In step 5, all sampling points of the binaural output signal are set to 0;
In step 6, each ambisonics channel signal is convolved with the HRTF in the corresponding direction of the channel, and the convolved signal is superimposed on the binaural output signal;
In step 7, step 6 is repeated for all ambisonics channels.

In this way, the number of convolutions is only related to the number of ambionics channels, and has nothing to do with the number of sound sources, and encoding the sound sources into Ambionics is much faster than convolution. Moreover, in a case where the listener rotates, all ambisonics channels can be rotated, and the amount of calculation also has nothing to do with the number of sound sources. In addition to rendering the ambisonics signal to both ears, it can also be simply rendered to the speaker array.

In the real world, human beings, as well as other animals, perceive not only the direct sound of the sound source directly reaching the ear, but also the vibration wave of the sound source reflected, scattered and diffracted by the environment. Environmental reflected and scattered sound directly affect the auditory perception of the sound source and the listener's own environment. This perception ability is the basic principle that nocturnal animals such as bats can locate their own positions in the dark and understand their own environment.

Humans may not as sensitive in hearing as bats, but they can also get a lot of information by listening to the influence of the environment on the sound source. For example, in a case of listening to a singer performing, due to different reverberation times, it is easy to distinguish whether one is hearing the performance in a large cathedral or in a parking lot. Because the ratio of reverberation to direct sound is different, even in the cathedral, it is possible to clearly distinguish whether one is listening to the song one meter directly in front of the singer or twenty meters directly in front of the singer. For example, also for the scene in the cathedral, due to the difference in the loudness of the early reflected sounds, it is possible to clearly distinguish whether one is listening to the singer singing in the center of the cathedral or only ten centimeters away from the wall.

The wave solver based on finite element analysis (wave physical simulation) divides the space to be calculated into densely arranged cubes, which are called “voxels” (similar to the concept of pixels, except that pixels are the smallest area units on the two-dimensional plane and voxels are the smallest units of volume in the three-dimensional space). The basic process of the algorithm is as follows:
In step 1, in the virtual scene, a pulse is excited in a voxel at the position of the sound source;
In step 2, in the next time segment, the pulses of all neighboring voxels of the voxel are calculated according to the voxel size and whether the neighboring voxels contain the scene shape;
In step 3, the sound field in the scene can be calculated by repeating step 2 for many times, and the more times it is repeated, the more accurate the calculation of the sound field will be;
In step 4, the array of all historical amplitudes on the position voxel of the listener's position is taken as the impulse response of the sound source to this listener's position in the current scene;
In step 5, steps 1-4 are repeated for all sound sources in the scene.

The house acoustic simulation algorithm based on the wave solver has the following advantages:

The accuracy of time and space is very high, and as long as a small enough voxel and a short enough time slice length are provided, it can be adapted to scenes of any shape and material.

At the same time, the algorithm has the following disadvantages:
1. The amount of computation is huge. The amount of computation is inversely proportional to the cube of the voxel size and directly proportional to the time slice length. In practical application scenario, it is almost impossible to calculate the wave physics in real time while ensuring reasonable time and space accuracy.
2. Because of the above defects, in a case where it is necessary to render the house acoustic phenomena in real time, software developers chooses to pre-render impulse responses between a large number of sound sources and listeners in different position combinations and parameterize them, and switch the rendering parameters in real time according to the different positions of the listener and the sound source during real-time calculation. However, this requires a powerful computing device for pre-rendering calculation and extra storage space to store a large number of parameters.
3. As mentioned above, this method cannot correctly reflect the change of acoustic characteristics of the scene in the case where unexpected changes occurred in the scene during pre-rendering, because the corresponding rendering parameters are not saved.

The core idea of the ray tracing algorithm is to find as many sound propagation paths as possible from the sound source to the listener, so as to obtain the energy direction, delay and filtering characteristics brought by these paths. This kind of algorithm is the core of the house acoustic simulation system of Oculus and Wwise.

The algorithm for finding the propagation path from the sound source to the listener can be simply summed up in the following steps:
In step 1, several rays evenly distributed on a spherical surface are emitted into the space by taking the position of the listener as the origin;
In step 2, for each ray:
a. In response to a vertical distance between the ray and a sound source being less than a preset value, the current path is recorded as an effective path of the sound source and is saved;
b. In the case where the ray intersects with the scene, the direction of the ray may be changed according to the preset material information of the triangle where the intersection point is located, and the ray continues to be emitted in the scene;
c. Repeat steps a and b until the number of reflections of the ray reaches the preset maximum reflection depth, then return to step 2 and perform steps a to c on the initial direction of the next ray.

So far, for each sound source, some path information is recorded. Then this information is used to calculate the energy direction, delay and filtering characteristics of each path of each sound source. These pieces of information are collectively referred to as the spatial impulse response between the sound source and the listener.

Finally, as long as the spatial impulse response of each sound source is auralized, very real orientation and distance of the sound source and the characteristics of the environment where the sound source and the listener are located can be simulated. There are two methods for auralizing the spatial impulse response:
1. Encode the spatial impulse response into a spherical harmonic domain (ambisonics domain), then use this spherical harmonic domain to generate a binaural room impulse response (BRIR), and finally convolve the original signal of the sound source with this BRIR to obtain the spatial audio with room reflection and reverberation;
2. Encode the original signal of the sound source into the spherical harmonic domain using the information of spatial impulse response, and then render the spherical harmonic to binaural output.

The environmental acoustic simulation algorithm based on ray tracing has the following advantages:
Compared with the wave physics simulation, the amount of computation is much lower, and pre-rendering is not needed;
It can adapt to dynamically changing scenes (e.g., door opening, material change, roof being blown off, etc.);
It can adapt to scenes of any shape.

This type of algorithm also has the following disadvantages:

The accuracy of the algorithm is extremely dependent on the sampling amount of the initial direction of the ray, that is, more rays. However, because the complexity of ray tracing algorithm is O(nlog(n)), more rays may inevitably bring an explosive increase in the amount of computation.

Whether BRIR convolution or encoding the original signal into the spherical harmonics, the amount of computation is very considerable. With the increase of the number of sound sources in the scene, the amount of computation may increase linearly, which is not very friendly for mobile devices with limited computing power.

The idea of the algorithm for simplifying the geometric shape of the environment is to try to find an approximate but much simpler geometric shape and surface material after the geometric shape and surface material of the current scene are given, so as to greatly reduce the computation amount of environmental acoustic simulation. The algorithm for simplifying the geometric shape of the environment includes:
In step 1, in the pre-rendering stage, the room shape of a cube is estimated;
In step 2, by using the geometric characteristics of the cube and meanwhile assuming that the sound source and the listener are in the same area, the direct sound and early reflections from the sound source to the listener in the scene are quickly calculated by using a table lookup method;
In step 3, in the pre-rendering stage, the empirical formula for the reverberation time of a cubic room is utilized to calculate the duration of the late reverberation in the current scene, so as to control an artificial reverberation to simulate the late reverberation effect of the scene.

This type of algorithm has the following advantages:
1. Extremely small amount of computation;
2. Theoretically, it can simulate an infinitely long reverberation time without additional CPU and memory overhead.

However, this type of algorithm has the following disadvantages:
1. The approximate shape of the scene is calculated in the pre-rendering stage, which cannot adapt to the dynamically changing scene (e.g., door opening, material change, roof being blown off, etc.);
2. It is assumed that the sound source and the listener are always in the same position, which is not realistic;
3. It is assumed that all scene shapes can be approximated as cubes with three sides parallel to the world coordinates, which cannot correctly render many real scenes (e.g., long and narrow corridors, inclined staircases, old and tilted containers, etc.);
4. This type of algorithm sacrifices the rendering quality in exchange for a fast rendering speed.

That is to say, the environmental acoustic simulation algorithm that simplifies the geometric shape of the environment provides a fast rendering speed, but sacrifices the rendering quality, and the rendering framework cannot support dynamically changing scenes, such as opening and closing doors.

Aiming at the above technical problems, the present disclosure renders the influence of the dynamically changing scenes on the environmental sound without significantly affecting the rendering speed, so that devices with weak computing power can also simulate the dynamic environmental sound of a large number of sound sources in real time. Therefore, the efficiency and accuracy of sound rendering can be improved.

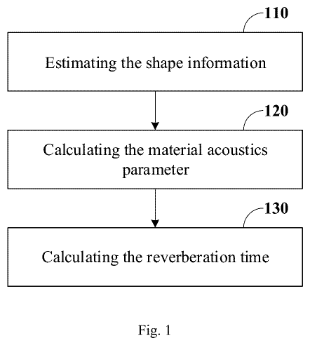

FIG. 1 shows a flow diagram of a reverberation processing method according to some embodiments of the present disclosure.

As shown in FIG. 1, in step 110, the shape information of a scene is estimated according to a plurality of intersection points of a plurality of sound rays centered on a listener with the scene.

In some embodiments, a coordinate of an average intersection point is calculated according to an average value of the coordinates of the plurality of intersection points; the shape information of the scene is estimated according to an average value of the distance between each of the plurality of intersection points and an average intersection point.

In some embodiments, the shape of the scene is a cube, and the shape information includes the side length of the cube. For example, the shape of the scene can also be other shapes such as a rectangular box.

For example, centered on the listener, N sound rays are randomly and evenly scattered around, and N intersection points Pₙ, n∈(1, N) of these sound rays with the scene are obtained. The coordinate of the average intersection point is calculated as follows:

$$\overline{P} = \frac{{\sum }_{n = 1}^{N} {P}_{n}}{N}$$

The shape information of an approximately cubic room is calculated: an average distance from all intersection points Pₙ to the coordinate P̅ of the average intersection point is calculated as follows:

$$\overline{D} = \frac{{\sum }_{n = 1}^{N} ‖ {P}_{n} - \overline{P} ‖}{N}$$

Where the side length of the cubic room is estimated to be 2D̅.

In step 120, a first average acoustic parameter value of a scene material of the scene is calculated according to first acoustic parameter values of the scene materials at the positions of the plurality of intersection points.

In some embodiments, an average absorption rate of the scene material of the scene is calculated according to an average value of absorption rates of the scene materials at the positions of the plurality of intersection points.

In some embodiments, a second average acoustic parameter value of the scene material of the scene is calculated according to second acoustic parameter values of the scene materials at the positions of the plurality of intersection points. For example, an average material scattering rate of the scene is calculated according to an average value of material scattering rates at the positions of the plurality of intersection points.

For example, the average acoustic parameter of the scene material is calculated. It is assumed that the absorption rate of the scene material is Aₙ and the scattering rate of the scene material is Sₙ at each intersection point Pₙ of the N sound rays with the scene mentioned above.

For example, the average absorption rate is:

$$\overline{A} = \frac{{\sum }_{n = 1}^{N} {A}_{n}}{N}$$

For example, the average scattering rate is:

$$\overline{S} = \frac{{\sum }_{n = 1}^{N} {S}_{n}}{N}$$

In step 130, the reverberation time is calculated according to the shape information of the scene and the first average acoustic parameter value. For example, the reverberation time is calculated according to the side length of the scene and the average absorption rate of the scene material of the scene.

In some embodiments, reverberation processing is performed on the sound source signal according to the second average acoustic parameter value and the reverberation time.

For example, the reverberation time is calculated by using the estimated cubic room, the average absorption rate of material and the Eyring formula:

$${T}_{60} = \frac{0.16 \times V}{- S \times ln ( 1 - \overline{A} )} = \frac{0.16 \times 8 \times {\overline{D}}^{3}}{- 4 \times {\overline{D}}^{2} \times ln ( 1 - \overline{A} )} = - \frac{0.32 \times \overline{D}}{ln ( 1 - \overline{A} )}$$

Where S is the indoor surface area of the cubic room, and V is the net volume of the cubic room.

In a case where the position of the listener changes, the sound rays emitted from the listener may intersect with different surfaces of the scene objects, causing the reverberation time T₆₀ and the average scattering rate S̅ calculated in the physical simulation process to change.

In some embodiments, reverberation processing is performed on the sound source signal according to the reverberation time.

In some embodiments, calculating an average scattering rate of the scene material of the scene according to an average value of scattering rates of the scene materials at the positions of the plurality of intersection points.

In some embodiments, performing filtering processing on the sound source signal using an all-pass filter, where the all-pass filter is controlled according to the second average acoustic parameter value.

In some embodiments, based on the result of the filtering processing, the reverberation processing is performed using one or more feedback gains, where the one or more feedback gains are controlled based on the reverberation time.

In some embodiments, one or more feedback gains are a plurality of feedback gains, and each of the plurality of feedback gains is determined according to the corresponding delay time.

For example, 16 feedback gains are controlled by the reverberation time T₆₀ as follows:

$$g ( n ) = {10}^{\frac{- 3 \times delay ( n )}{T 60}} , n ∈ [ 0 , 15 ]$$

Where delay(n) is the delay time corresponding to the feedback gain n.

In some embodiments, delay processing is performed on the result of the filtering processing; the result of the delay processing is processed using a reflection matrix; a processing result of the reflection matrix is processed using the one or more feedback gains.

In some embodiments, the second average acoustic parameter of the scene material includes the scattering rate of the scene material; the All-pass filter is set according to the scattering rate of the scene material.

In some embodiments, a plurality of delay times are used to respectively perform delay processing on the result of filtering processing.

In some embodiments, the delay processing is performed on a sum of the result of the filtering processing and the processing result using one or more feedback gains.

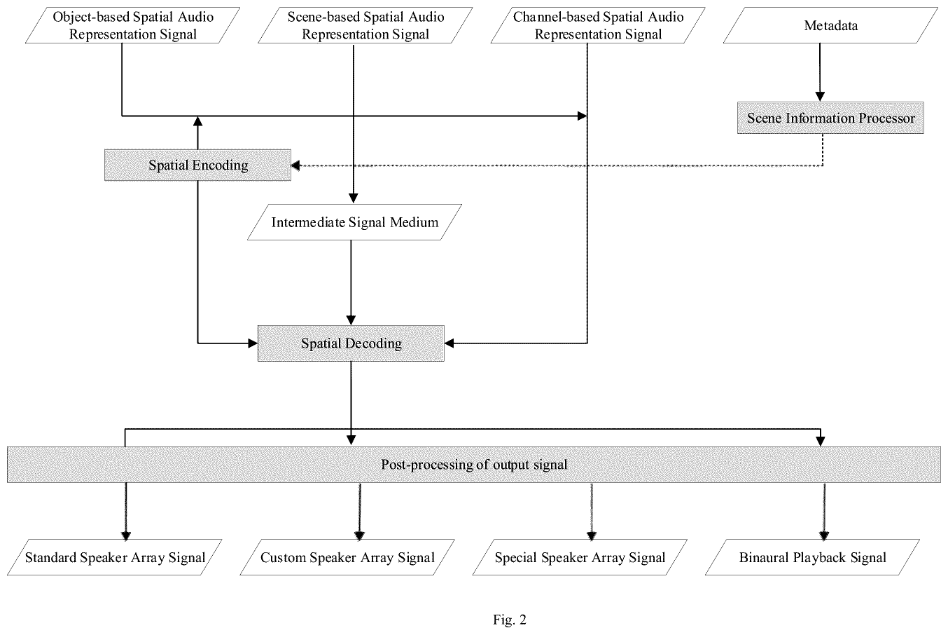

FIG. 2 shows a schematic diagram of a spatial audio rendering system framework according to some embodiments of the present disclosure.

As shown in FIG. 2, the scene shape (3D mesh), the position of the listener, the absorption rate of walls (such as walls corresponding to the scene and the intersection points, etc.), the scattering rate of the wall and the distance attenuation information are derived from the “metadata” part in FIG. 2. For example, the binaural playback signal in FIG. 2 can be generated by the following embodiment.

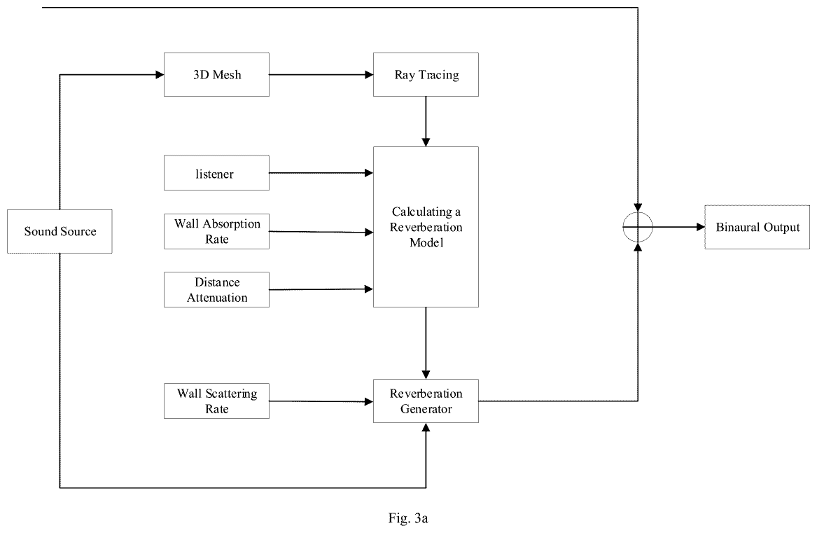

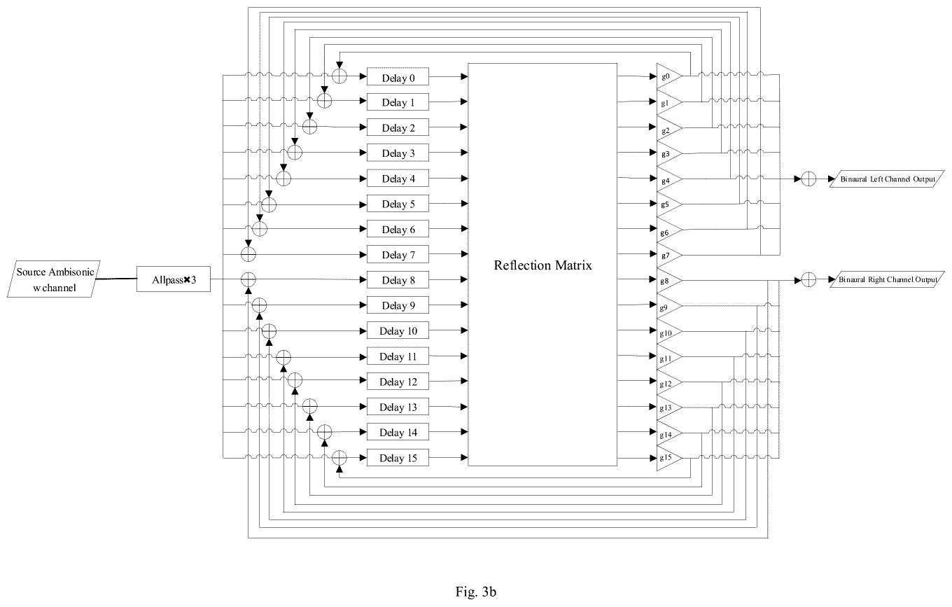

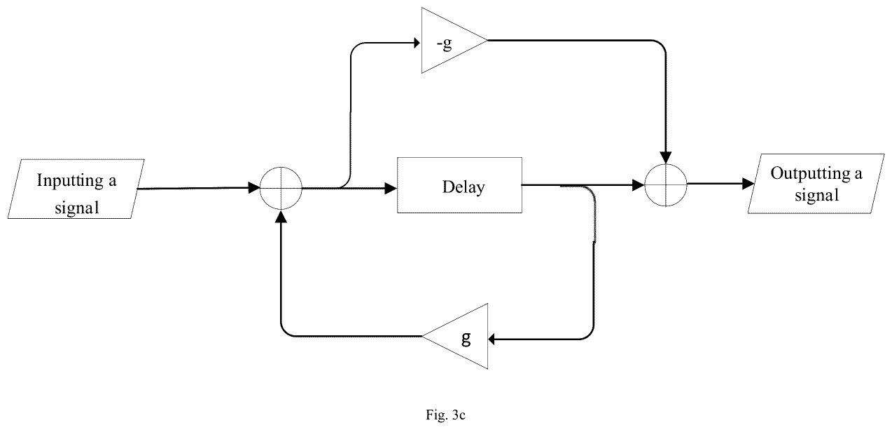

FIGS. 3a to 3c show schematic diagrams of a reverberation processing method according to some embodiments of the present disclosure.

As shown in FIG. 3a, the framework of the rendering processing includes: assuming that the sound emitted by the sound source is several sound rays emitted from the sound source; simulating physical phenomena such as air propagation, reflection, refraction in the scene, and collecting the intensity of the sound rays that finally converges to the listener's ears; considering the factors of absorption rate of the wall and the distance in the process of sound ray propagation, estimating the calculation model of the scene through the intensity of sound rays; using the generated reverberation model to perform reverberation processing on the audio data of the sound source; mixing the reverberation data with the spatialized binaural data to output the final binaural audio.

In some embodiments, the input information for calculating the reverberation model is the scene shape, the absorption rate of the scene, the scattering rate of the scene and the position of the listener.

Centered on the listener, N sound rays are randomly and evenly scattered around, and N intersection points Pₙ, n∈(1,N) of these sound rays with the scene are obtained. The coordinate of the average intersection point is calculated as follows:

$$\overline{P} = \frac{{\sum }_{n = 1}^{N} {P}_{n}}{N}$$

The shape information of an approximately cubic room is calculated: the average distance from all intersection points Pₙ to the coordinate P̅ of the average intersection point is calculated as follows:

$$\overline{D} = \frac{{\sum }_{n = 1}^{N} ‖ {P}_{n} - \overline{P} ‖}{N}$$

It is assumed that the side length of the cubic room is 2D̅.

The average acoustic parameter of the scene material is calculated. It is assumed that the absorption rate of the scene material is Aₙ and the scattering rate of the scene material is Sₙ at each intersection point Pₙ of the N sound rays with the scene mentioned above.

For example, the average absorption rate is:

$$\overline{A} = \frac{{\sum }_{n = 1}^{N} {A}_{n}}{N}$$

For example, the average scattering rate is:

$$\overline{S} = \frac{{\sum }_{n = 1}^{N} {S}_{n}}{N}$$

For example, the reverberation time is calculated by using the estimated cubic room, the average absorption rate of material and the Eyring formula:

$${T}_{60} = \frac{0.16 \times V}{- S \times ln ( 1 - \overline{A} )} = \frac{0.16 \times 8 \times {\overline{D}}^{3}}{- 4 \times {\overline{D}}^{2} \times ln ( 1 - \overline{A} )} = - \frac{0.32 \times \overline{D}}{ln ( 1 - \overline{A} )}$$

In a case where the position of the listener changes, the rays emitted from the listener may intersect with different surfaces of the scene objects, causing the reverberation time T₆₀ and the average scattering rate S̅ calculated in the physical simulation process to change.

Corresponding to these changing sound field parameters, a reverberation processing link that can dynamically adjust the reverberation time and the time-domain density of reflected sounds during operation is proposed, so that the calculated changing sound field parameters can dynamically affect the heard reverberation sound, thus realizing dynamic reverberation related to the scene. Dynamic reverberation can produce different reverberation effects for the 6DoF (6 Degrees of Freedom) movement following the listener.

The input signal of the dynamic reverberator is the original signal of the sound source or the original sound source signal processed by one or more of the following effectors: loudness attenuation, air absorption filtering, delay effect processing or spatialization algorithm.

There are many implementation methods for this dynamically adjustable artificial reverberator, one of the embodiments is shown in FIG. 3b. The “Allpass×3” filter uses three cascaded all-pass filters (such as Schroder Allpass).

The structure of Schroder Allpass filter is shown in FIG. 3c, and the delay time is 5˜10 ms and they are mutually prime numbers. Parameter g of Schroder Allpass filter is controlled by the average scattering coefficient S̅:

$$g = 1 - 0.3 \times \overline{S}$$

The coefficient 0.3 can also be replaced by other values as required. The larger the value of g, the more dispersed the input energy is on the time axis.

As shown in FIG. 3b, the delay time of delay 0˜15 is 30˜50 ms and they are mutually prime numbers. The reflection matrix is a 16×16 Householder matrix. g0˜g15 are 16 feedback gains, which are controlled by the reverberation time T₆₀

$$g ( n ) = {10}^{\frac{- 3 \times delay ( n )}{T 60}} , n ∈ [ 0 , 15 ]$$

Where delay(n) is the delay time corresponding to the nth feedback gain.

In the above embodiments, the reverberation model in the dynamically changing scene is calculated by estimating the simplified shape of the room in real time; the dynamically adjustable artificial reverberation is controlled by the reverberation model. In this way, the influence of the dynamically changing scene on the environmental sound can be rendered without significantly affecting the rendering speed, so that devices with weak computing power can also simulate the dynamic ambient sound of a large number of sound sources in real time. Therefore, the efficiency and accuracy of sound rendering can be improved.

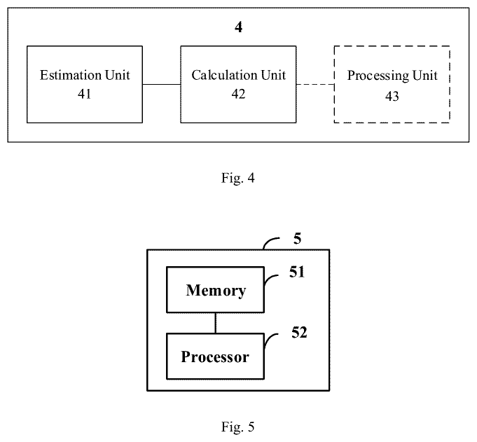

FIG. 4 shows a block diagram of a reverberation processing device according to some embodiments of the present disclosure.

As shown in FIG. 4, a reverberation processing device 4 includes: an estimation unit 41 configured to estimate shape information of a scene according to a plurality of intersection points of a plurality of sound rays centered on a listener with the scene; a calculation unit 42 configured to calculate a first average acoustic parameter value of a scene material of the scene according to first acoustic parameter values of scene materials at positions of the plurality of intersection points, and calculate a reverberation time according to the shape information of the scene and the first average acoustic parameter value.

In some embodiments, the estimation unit 41 calculates a coordinate of an average intersection point according to an average value of coordinates of the plurality of intersection points, and estimates the shape information of the scene according to an average value of a distance between each of the plurality of intersection points and an average intersection point.

In some embodiments, the calculation unit 42 calculates an average absorption rate of the scene material of the scene according to an average value of absorption rates of the scene materials at the positions of the plurality of intersection points.

In some embodiments, a shape of the scene is a cube, and the shape information includes a side length of the cube.

In some embodiments, the calculation unit 42 calculates the reverberation time according to a side length of the scene and the average absorption rate of the scene material of the scene.

In some embodiments, the calculation unit 42 calculates a second average acoustic parameter value of the scene material of the scene according to second acoustic parameter values of the scene materials at the positions of the plurality of intersection points; the processing device 4 further includes a processing unit 43 configured to perform a reverberation processing on a sound source signal according to the second average acoustic parameter value and the reverberation time.

In some embodiments, the calculation unit 42 calculates an average scattering rate of the scene material of the scene according to an average value of scattering rates of the scene materials at the positions of the plurality of intersection points.

In some embodiments, the processing unit 43 performs a filtering processing on the sound source signal using an all-pass filter, where the all-pass filter is controlled according to the second average acoustic parameter value.

In some embodiments, the processing unit 43 performs the reverberation processing using one or more feedback gains based on a result of the filtering processing, where the one or more feedback gains are controlled according to the reverberation time.

In some embodiments, the one or more feedback gains are a plurality of feedback gains, and each of the plurality of feedback gains is determined according to a corresponding delay time.

In some embodiments, the processing unit 43 performs a delay processing on the result of the filtering processing, processes a result of the delay processing using a reflection matrix, and processes a processing result of the reflection matrix using the one or more feedback gains.

In some embodiments, the processing unit 43 performs the delay processing on the result of the filtering processing respectively using a plurality of delay times.

In some embodiments, the processing unit 43 performs the delay processing on a sum of the result of the filtering processing and a processing result using one or more feedback gains.

FIG. 5 shows a block diagram of a reverberation processing device according to other embodiments of the present disclosure.

As shown in FIG. 5, a reverberation processing device 5 of this embodiment includes a memory 51 and a processor 52 coupled to the memory 51, and the processor 52 is configured to carry out a reverberation processing method in any one of the embodiments of the present disclosure based on instructions stored in the memory 51.

The memory 51 may include, for example, a system memory, a fixed non-volatile storage medium, and the like. The system memory stores, for example, an operating system, an application program, a Boot Loader, a database and other programs.

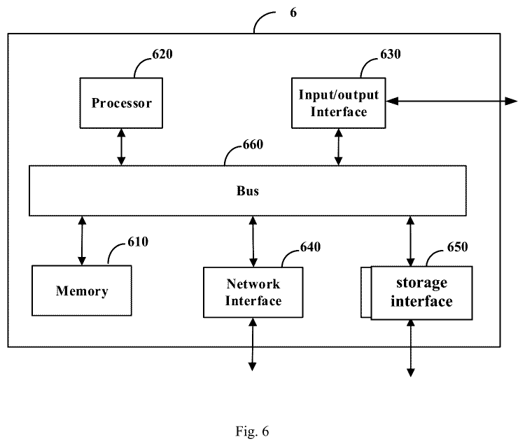

FIG. 6 shows a block diagram of a reverberation processing device according to further embodiments of the present disclosure.

As shown in FIG. 6, a reverberation processing device 6 of this embodiment includes: a memory 610 and a processor 620 coupled to the memory 610, the processor 620 being configured to carry out a reverberation processing method of any one of the embodiments described above based on instructions stored in the memory 610.

Memory 610 may include, for example, a system memory, a fixed non-volatile storage medium, and the like. The system memory stores, for example, an operating system, an application program, a Boot Loader, and other programs.

The reverberation processing device 6 may also include an input/output interface 630, a network interface 640, a storage interface 650, and etc. These interfaces 630, 640, 650 and the memory 610 and the processor 620 may be connected by a bus 660, for example. The input/output interface 630 provides a connection interface for input/output devices such as a display, a mouse, a keyboard, a touch screen, a microphone, and a sound box. The network interface 640 provides a connection interface for various networking devices. The storage interface 650 provides a connection interface for an external storage device such as an SD card and a U disk.

It shall be understood by those skilled in the art that the embodiments of the present disclosure may be provided as a method, a system, or a computer program product. Therefore, embodiments of the present disclosure can take the form of an entirely hardware embodiment, an entirely software embodiment or an embodiment containing both hardware and software elements. Moreover, the present disclosure may take the form of a computer program product embodied on one or more computer-usable non-transitory storage media (including but not limited to disks, CD-ROM, optical storage, etc.) having computer-usable program code embodied in the medium.

Heretofore, all the embodiments of the present disclosure have been described in detail. In order to avoid shielding of the concept of the present disclosure, some details commonly known in the art are not described. Based on the above description, those skilled in the art can fully understand how to carry out the technical solutions disclosed here.

The method and system of the present disclosure may be implemented in a number of ways. For example, the method and system of the present disclosure may be implemented in software, hardware, firmware, or any combination of software, hardware, and firmware. The above order of the steps of the method is for illustration only, and the steps of the method of the present disclosure are not limited to the order specifically described above unless specifically stated otherwise. Further, in some embodiments, the present disclosure may also be implemented as programs recorded in a recording medium, the programs including machine-readable instructions for implementing the method according to the present disclosure. Thus, the present disclosure also covers a recording medium storing a program for executing the method according to the present disclosure.

Although some specific embodiments of the present disclosure have been exemplified in detail, it shall be understood by those skilled in the art that the above examples are only illustrative, but shall by no means limit the scope of the present disclosure. Those skilled in the art will appreciate that the above embodiments may be modified without departing from the scope and spirit of the present disclosure. The scope of the present disclosure is defined by the appended claims.

What is claimed is:

1. A reverberation processing method, comprising:
estimating shape information of a scene according to a plurality of intersection points of a plurality of sound rays centered on a listener with the scene;
calculating a first average acoustic parameter value of a scene material of the scene according to first acoustic parameter values of scene materials at positions of the plurality of intersection points; and
calculating a reverberation time according to the shape information of the scene and the first average acoustic parameter value.

2. The reverberation processing method according to claim 1, wherein the estimating the shape information of the scene according to the plurality of intersection points of the plurality of sound rays centered on the listener with the scene comprises:
calculating a coordinate of an average intersection point according to an average value of coordinates of the plurality of intersection points; and
estimating the shape information of the scene according to an average value of distances between each of the plurality of intersection points and the average intersection point.

3. The reverberation processing method according to claim 1, wherein the calculating the first average acoustic parameter value of the scene material of the scene according to the first acoustic parameter values of the scene materials at the positions of the plurality of intersection points comprises:
calculating an average absorption rate of the scene material of the scene according to an average value of absorption rates of the scene materials at the positions of the plurality of intersection points.

4. The reverberation processing method according to claim 1, wherein a shape of the scene is a cube, and the shape information comprises a side length of the cube.

5. The reverberation processing method according to claim 4, wherein the calculating the reverberation time according to the shape information of the scene and the first average acoustic parameter value comprises:
calculating the reverberation time according to a side length of the scene and the average absorption rate of the scene material of the scene.

6. The reverberation processing method according to claim 1, further comprising:
calculating a second average acoustic parameter value of the scene material of the scene according to second acoustic parameter values of the scene materials at the positions of the plurality of intersection points; and
performing a reverberation processing on a sound source signal according to the second average acoustic parameter value and the reverberation time.

7. The reverberation processing method according to claim 6, wherein the calculating the second average acoustic parameter value of the scene material of the scene according to the second acoustic parameter values of the scene materials at the positions of the plurality of intersection points comprises:
calculating an average scattering rate of the scene material of the scene according to an average value of scattering rates of the scene materials at the positions of the plurality of intersection points.

8. The reverberation processing method according to claim 6, wherein the performing the reverberation processing on the sound source signal comprises:
performing a filtering processing on the sound source signal using an all-pass filter, wherein the all-pass filter is controlled according to the second average acoustic parameter value.

9. The reverberation processing method according to claim 7, wherein the performing the reverberation processing on the sound source signal comprises:
performing the reverberation processing using one or more feedback gains based on a result of the filtering processing, wherein the one or more feedback gains are controlled according to the reverberation time.

10. The reverberation processing method according to claim 9, wherein the one or more feedback gains are a plurality of feedback gains, and each of the plurality of feedback gains is determined according to a corresponding delay time.

11. The reverberation processing method according to claim 9, wherein the performing the reverberation processing using the one or more feedback gains based on the result of the filtering processing comprises:
performing a delay processing on the result of the filtering processing;
processing a result of the delay processing using a reflection matrix; and
processing a processing result of the reflection matrix using the one or more feedback gains.

12. The reverberation processing method according to claim 11, wherein the performing the delay processing on the result of the filtering processing comprises:
performing the delay processing on the result of the filtering processing respectively using a plurality of delay times.

13. The reverberation processing method according to claim 11, wherein the performing the delay processing on the result of the filtering processing comprises:
performing the delay processing on a sum of the result of the filtering processing and a processing result using the one or more feedback gains.

14. A reverberation processing device, comprising:
a memory; and
a processor coupled to the memory, the processor configured to carry out a reverberation processing method, comprising:
estimating shape information of a scene according to a plurality of intersection points of a plurality of sound rays centered on a listener with the scene;
calculating a first average acoustic parameter value of a scene material of the scene according to first acoustic parameter values of scene materials at positions of the plurality of intersection points; and
calculating a reverberation time according to the shape information of the scene and the first average acoustic parameter value.

15. The reverberation processing device according to claim 14, wherein the processor is configured to carry out following steps:
calculating a coordinate of an average intersection point according to an average value of coordinates of the plurality of intersection points; and
estimating the shape information of the scene according to an average value of distances between each of the plurality of intersection points and the average intersection point.

16. The reverberation processing device according to claim 14, wherein the processor is configured to carry out a following step:
calculating an average absorption rate of the scene material of the scene according to an average value of absorption rates of the scene materials at the positions of the plurality of intersection points.

17. The processing device according to claim 14, wherein a shape of the scene is a cube, and the shape information comprises a side length of the cube.

18. The reverberation processing device according to claim 17, wherein the processor is configured to carry out a following step:
calculating the reverberation time according to a side length of the scene and the average absorption rate of the scene material of the scene.

19. The reverberation processing device according to claim 14, wherein the processor is configured to carry out following steps:
calculating a second average acoustic parameter value of the scene material of the scene according to second acoustic parameter values of the scene materials at the positions of the plurality of intersection points; and
performing a reverberation processing on a sound source signal according to the second average acoustic parameter value and the reverberation time.

20. A non-transitory computer-readable storage medium stored thereon a computer program that, when executed by a processor, carries out a reverberation processing method, comprising:
estimating shape information of a scene according to a plurality of intersection points of a plurality of sound rays centered on a listener with the scene;
calculating a first average acoustic parameter value of a scene material of the scene according to first acoustic parameter values of scene materials at positions of the plurality of intersection points; and
calculating a reverberation time according to the shape information of the scene and the first average acoustic parameter value.
